(19) United States
(12) Patent Application Publication
(10) Pub. No.: US 2023/0375800 A1
(43) Pub. Date: Nov. 23, 2023

(54) SEMICONDUCTOR DEVICE AND OPTICAL STRUCTURE BODY

(71) Applicant: SONY GROUP CORPORATION, Tokyo (JP)

(72) Inventor: Hideaki OKANO, Tokyo (JP)

(73) Assignee: SONY GROUP CORPORATION, Tokyo (JP)

(21) Appl. No.: 18/247,117

(22) PCT Filed: Sep. 22, 2021
(86) PCT No.: PCT/JP2021/034831

§ 371 Date: Mar. 29, 2023

(30) Foreign Application Priority Data
Oct. 5, 2020 (JP) 2020-168378

(51) Int. Cl. G02B 7/02; G01S 7/481

(52) U.S. Cl. CPC G02B 7/021; G01S 7/4811; G01S 17/894

(57) ABSTRACT

The present technology relates to a semiconductor device and an optical structure body that can downsize the semiconductor device. Provided are: a plurality of first optical structure bodies arranged in a first optical axis direction; and a plurality of second optical structure bodies arranged in a second optical axis direction, at least one of the plurality of first optical structure bodies and at least one of the plurality of second optical structure bodies arranged in a direction perpendicular to the optical axis directions being optical structure bodies having a structure in which the first optical structure body and the second optical structure body are continuous. The first optical structure body and the second optical structure body have different optical characteristics. The present technology can be applied to semiconductor devices such as a distance measurement device that performs distance measurement and an imaging device that images an image.

### TECHNICAL FIELD

The present technology relates to a semiconductor device and an optical structure body, and for example, to a semiconductor device and an optical structure body that can be further downsized.

### BACKGROUND ART

Imaging devices such as a camera-equipped mobile phone and a digital still camera using an imaging element such as a charge coupled device (CCD) or a complementary metal oxide semiconductor (CMOS) image sensor are known. A time of flight (TOF) sensor is known as a distance measurement device that measures a distance to an object using the imaging element (see, for example, Patent Document 1).

### CITATION LIST

### Patent Document

Patent Document 1: Japanese Patent Application Laid-Open No. 2019-132640

### SUMMARY OF THE INVENTION

### Problems to be Solved by the Invention

In Patent Document 1, a lens holder that holds a lens on a light emitting side and a lens holder that holds a lens on a light receiving side are provided. Since the lens holder on the light emitting side and the lens holder on the light receiving side are separately manufactured, there is a possibility that time required for manufacturing the both becomes long. Furthermore, it is difficult to reduce a size since the two lens holders are provided. It is desired to reduce the size and manufacturing time of the distance measuring device and an imaging device.

The present technology has been made in view of such a situation, and an object thereof is to enable downsizing and shortening of time required for manufacturing.

### Solutions to Problems

A semiconductor device according to one aspect of the present technology includes: a plurality of first optical structure bodies arranged in a first optical axis direction; and a plurality of second optical structure bodies arranged in a second optical axis direction, at least one of the plurality of first optical structure bodies and at least one of the plurality of second optical structure bodies arranged in a direction perpendicular to the optical axis directions being optical structure bodies having a structure in which the first optical structure body and the second optical structure body are continuous.

An optical structure body according to one aspect of the present technology has a structure in which a first optical structure body and a second optical structure body respectively having optical surfaces at different positions in an optical axis direction are continuous.

The semiconductor device according to one aspect of the present technology is provided with: the plurality of first optical structure bodies arranged in the first optical axis direction; and the plurality of second optical structure bodies arranged in the second optical axis direction, and at least one of the plurality of first optical structure bodies and at least one of the plurality of second optical structure bodies arranged in the direction perpendicular to the optical axis directions forms the optical structure body having the structure in which the first optical structure body and the second optical structure body are continuous.

The optical structure body according to one aspect of the present technology has the structure in which the first optical structure body and the second optical structure body respectively having the optical surfaces at the different positions in the optical axis direction are continuous.

Note that the semiconductor device may be an independent device or an internal block constituting one device.

### BRIEF DESCRIPTION OF DRAWINGS

FIG. 1 is a diagram depicting a configuration of an embodiment of a semiconductor device to which the present technology is applied.

FIG. 2 is a diagram depicting a configuration example of a light receiving section.

FIG. 3 is a diagram depicting a configuration example of the semiconductor device.

FIG. 4 is a diagram depicting another configuration example of the semiconductor device.

FIG. 5 is a diagram for explaining that downsizing can be achieved.

FIG. 6 is a diagram for explaining a configuration of a lens.

FIG. 7 is a diagram depicting another configuration example of the semiconductor device.

FIG. 8 is a diagram depicting still another configuration example of the semiconductor device.

FIG. 9 is a diagram depicting still another configuration example of the semiconductor device.

FIG. 10 is a diagram depicting still another configuration example of the semiconductor device.

FIG. 11 is a block diagram depicting an example of a schematic configuration of a vehicle control system.

FIG. 12 is a diagram of assistance in explaining an example of installation positions of an outside-vehicle information detecting section and an imaging section.

### MODE FOR CARRYING OUT THE INVENTION

Hereinafter, modes for carrying out the present technology (hereinafter, referred to as embodiments) will be described.

The present technology can be applied to a distance measurement device that performs distance measurement by, for example, a direct TOF scheme or an indirect TOF scheme. The present technology can also be applied to an imaging device or the like that images a subject and acquires a color image. The present technology can also be applied to a sensor that does not output an image, for example, a proximity sensor or the like. Here, a device to which the present technology can be applied will be described as a semiconductor device.

For example, the distance measurement device can be applied to a vehicle-mounted system that is mounted on a vehicle and measures a distance to an object outside the vehicle, a gesture recognition system that measures a distance to an object such as a hand of a user and recognizes a gesture of the user on the basis of a measurement result, and the like. In this case, a result of the gesture recognition can be used for, for example, an operation of a car navigation system or the like.

<Configuration Example of Semiconductor Device>

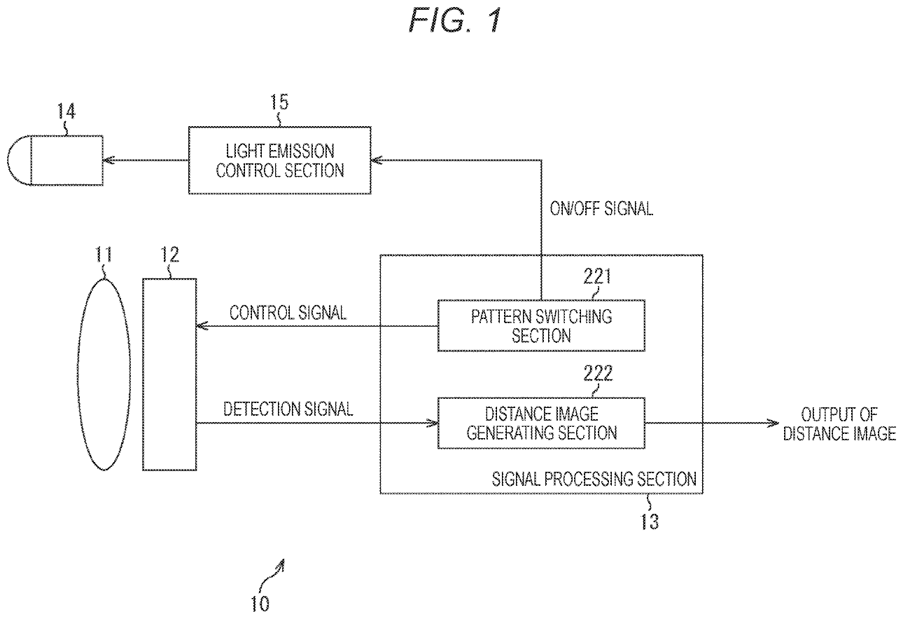

FIG. 1 illustrates a configuration example of an embodiment of a semiconductor device to which the present technology is applied. Here, a case where the present technology is applied to a device that performs distance measurement will be described as an example.

A semiconductor device 10 includes a lens 11, a light receiving section 12, a signal processing section 13, a light emitting section 14, and a light emission control section 15. The signal processing section 13 includes a pattern switching section 21 and a distance image generating section 22. The semiconductor device 10 in FIG. 1 irradiates an object with light and receives light (reflection light) of the light (irradiation light) reflected from the object, thereby measuring a distance to the object.

A light emitting system of the semiconductor device 10 includes the light emitting section 14 and the light emission control section 15. In the light emitting system, the light emission control section 15 causes the light emitting section 14 to emit infrared light (IR) under the control of the signal processing section 13. An IR band filter may be provided between the lens 11 and the light receiving section 12, and the light emitting section 14 may be configured to emit infrared light corresponding to a transmission wavelength band of the IR band filter.

The light emitting section 14 may be arranged in a housing of the semiconductor device 10 or may be arranged outside the housing of the semiconductor device 10. The light emission control section 15 causes the light emitting section 14 to emit light in a predetermined pattern. This pattern is set by the pattern switching section 21, and is configured to be switched at a predetermined timing.

The pattern switching section 21 may be provided, and the light emission pattern may be switched so as not to overlap with a pattern of another semiconductor device 10, for example. Furthermore, it is also possible to adopt a configuration in which such a pattern switching section 21 is not provided.

The signal processing section 13 functions as, for example, a calculator that calculates the distance from the semiconductor device 10 to the object on the basis of an image signal supplied from the light receiving section 12. In a case where the calculated distance is output as an image, the distance image generating section 22 of the signal processing section 13 generates and outputs a distance image in which the distance to the object is represented for each pixel.

<Configuration of Light Receiving Section>

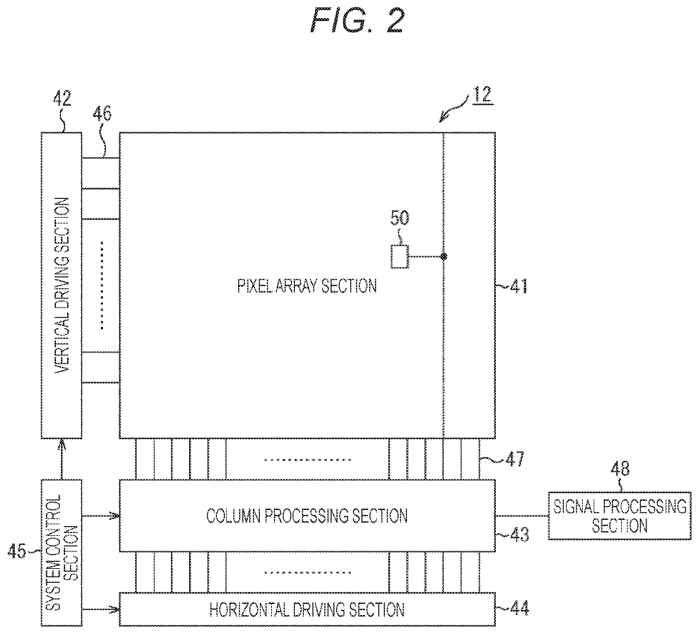

FIG. 2 is a block diagram illustrating a configuration example of the light receiving section 12. The light receiving section 12 can be a complementary metal oxide semiconductor (CMOS) image sensor.

The light receiving section 12 includes a pixel array section 41, a vertical drive section 42, a column processing section 43, a horizontal drive section 44, and a system control section 45. The pixel array section 41, the vertical drive section 42, the column processing section 43, the horizontal drive section 44, and the system control section 45 are provided on a semiconductor substrate (chip) (not depicted).

In the pixel array section 41, unit pixels having photoelectric conversion elements that generate and store therein photoelectric charges of a charge amount according to the amount of incident light are two-dimensionally arranged in a matrix.

Moreover, in the pixel array section 41, a pixel drive line 46 is further provided for each row along the left-right direction in the drawing (an array direction of pixels in the pixel row) with respect to the pixel array in the matrix form and a vertical signal line 47 is provided for each column along the up-down direction in the drawing (an array direction of pixels in the pixel column). The pixel drive line 46 has one end connected to an output end corresponding to each row of the vertical drive section 42.

The vertical drive section 42 includes a shift register, an address decoder, and the like, and is a pixel drive section that drives each pixel of the pixel array section 41, for example, at the same time for all the pixels or in units of rows. A pixel signal output from each unit pixel of a pixel row selected and scanned by the vertical drive section 42 is supplied to the column processing section 43 through each of the vertical signal lines 47. The column processing section 43 performs predetermined signal processing on the pixel signal output from each unit pixel of the selected row through the vertical signal line 47 for each pixel column of the pixel array section 41, and temporarily holds the pixel signal after the signal processing.

Specifically, as the signal processing, the column processing section 43 performs at least noise removal processing, for example, correlated double sampling (CDS). Through the correlated double sampling by the column processing section 43, fixed pattern noise unique to the pixel, such as reset noise or a threshold variation of an amplification transistor, is removed. Note that it is also possible to provide the column processing section 43 with, for example, an analog-to-digital (AD) conversion function in addition to the noise removal processing such that a signal level is output as a digital signal.

The horizontal drive section 44 includes a shift register, an address decoder, and the like, and sequentially selects unit circuits corresponding to the pixel columns of the column processing section 43. Through the selective scanning by the horizontal drive section 44, the pixel signals that have been subjected to the signal processing by the column processing section 43 are sequentially output to the signal processing section 48.

The system control section 45 includes a timing generator or the like that generates various timing signals, and performs driving control of the vertical drive section 42, the column processing section 43, the horizontal drive section 44, and the like on the basis of the various timing signals generated by the timing generator.

In the pixel array section 41, the pixel drive line 46 is wired along a row direction for each pixel row and two vertical signal lines 47 are wired along a column direction for each pixel column with respect to the pixel array in the matrix form. For example, the pixel drive line 46 transmits a drive signal for performing driving when a signal is read from a pixel. Note that the pixel drive line 46 is depicted as one wiring in FIG. 2, but is not limited to one. The pixel drive line 46 has one end connected to an output end corresponding to each row of the vertical drive section 42.

<Cross-Sectional Configuration Example of Semiconductor Device>

Next, configuration examples of semiconductor devices will be described. In the following description, a semiconductor device including two lens holders and a semiconductor device including one lens holder will be described. The semiconductor device including two lens holders will be described as a semiconductor device 100, and the semiconductor device including one lens holder will be described as the semiconductor device 10. The semiconductor device 100 can be used as the semiconductor device 10 described above.

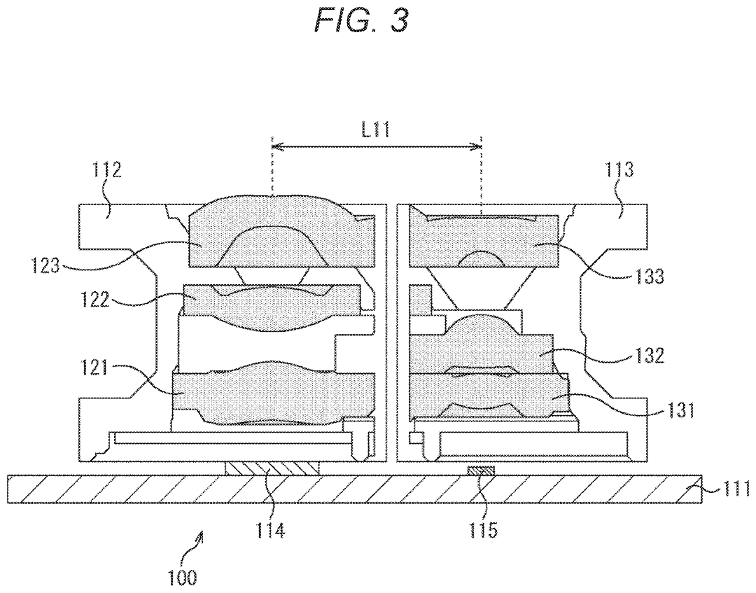

FIG. 3 is a diagram depicting a cross-sectional configuration example of the semiconductor device. The semiconductor device 100 has a configuration in which a light-receiving-side lens holder 112 that holds a lens on a light receiving side and a light-emitting-side lens holder 113 that holds a lens on a light emitting side are mounted on a substrate 111. An imaging element 114 as a light receiving element that receives incident light is arranged between the light-receiving-side lens holder 112 and the substrate 111. A light emitting section 115 is arranged between the light-emitting-side lens holder 113 and the substrate 111.

Note that the imaging element will be described as an example of the light receiving element is described here, but the present technology can also be applied to a light receiving element other than the imaging element used to receive incident light and generate an image.

The light-receiving-side lens holder 112 holds three lenses including a lens 121, a lens 122, and a lens 123. The light-emitting-side lens holder 113 holds a lens 131, a lens 132, and a lens 133. The light-receiving-side lens holder 112 and the light-emitting-side lens holder 113 are arranged with a predetermined interval.

The light emitted by the light emitting section 115 passes through the lenses 131 to 133 and is applied to an object. Measurement light that is reflection light reflected from the object forms an image in the imaging element 114 by the lenses 121 to 123.

A distance between a center of the lenses 121 to 123 held by the light-receiving-side lens holder 112 and a center of the lenses 131 to 133 held by the light-emitting-side lens holder 113 is described as a baseline length. The baseline length of the semiconductor device 100 depicted in FIG. 3 is a baseline length L11.

Since the light-receiving-side lens holder 112 and the light-emitting-side lens holder 113, which have been separately designed and assembled, are arranged on the substrate 111 with the predetermined interval in the semiconductor device 100, there is a limit in shortening the baseline length L11. Since the limit exists in shortening the baseline length L11, there is also a limit in downsizing the semiconductor device 100 itself. Furthermore, it is necessary to assemble different optical systems of the light-receiving-side lens holder 112 and the light-emitting-side lens holder 113 by different production processes, and thus, there is also a limit in further shortening time required at the time of manufacturing.

Therefore, the semiconductor device 10 that can be further downsized and can shorten time required for manufacturing will be described hereinafter.

<Another Configuration of Semiconductor Device>

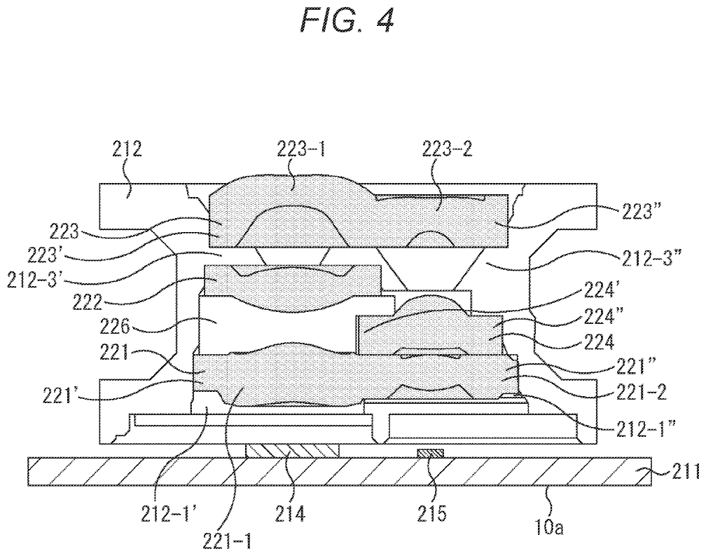

FIG. 4 is a diagram depicting another configuration example of the semiconductor device. The semiconductor device depicted in FIG. 4 is a semiconductor device including one lens holder, and the semiconductor device 10 depicted in FIG. 4 will be described as a semiconductor device 10a according to a first embodiment to be distinguished from the other embodiments since a plurality of embodiments will be described regarding the semiconductor device including one lens holder.

The semiconductor device 10a has a configuration in which a lens holder 212 that holds a lens on a light receiving side and a lens on a light emitting side is mounted on a substrate 211. It is assumed that the left side and the right side in FIG. 4 are the light receiving side and the light emitting side, respectively. On the light receiving side, an imaging element 214 as a light receiving element is arranged between the lens holder 212 and the substrate 211. On the light emitting side, a light emitting section 215 including a light emitting element is arranged between the lens holder 212 and the substrate 211. The lens holder 212 holds four lenses including a lens 221, a lens 222, a lens 223, and a lens 224.

The lens holder 212 and the lenses 221 to 223 correspond to, for example, the lens 11 of the semiconductor device 10 in FIG. 1. The imaging element 214 corresponds to, for example, the light receiving section 12 of the semiconductor device 10 in FIG. 1, and has a configuration in which pixels 50 are arranged on a matrix as depicted in FIG. 2.

The lens holder 212, the lenses 221, 223, and 224, and the light emitting section 215 correspond to the light emitting section 14 of the semiconductor device 10 in FIG. 1. The light emitting section 215 emits light having any wavelength such as visible light or infrared light as emission light. For example, any wavelength of the emission light is arbitrarily selected according to a use of the semiconductor device 10a.

The lens holder 212 holds lenses on the light receiving side and the light emitting side. The lenses held by the lens holder 212 also include a lens in which a lens on the light receiving side and a lens on the light emitting side are integrated. The lens 221 held by the lens holder 212 is a lens having a configuration in which a lens 221-1 used as a lens on the light receiving side and a lens 221-2 used as a lens on the light emitting side are integrated.

The lens 223 held by the lens holder 212 is a lens having a configuration in which a lens 223-1 used as a lens on the light receiving side and a lens 223-2 used as a lens on the light emitting side are integrated.

In the semiconductor device 10a depicted in FIG. 4 as well, light emitted by the light emitting section 215 passes through the lenses 221-2, 224, and 223-2 and is applied to an object. Measurement light that is reflection light reflected by the object forms an image in the imaging element 214 by the lenses 221-1, 222, and 223-1.

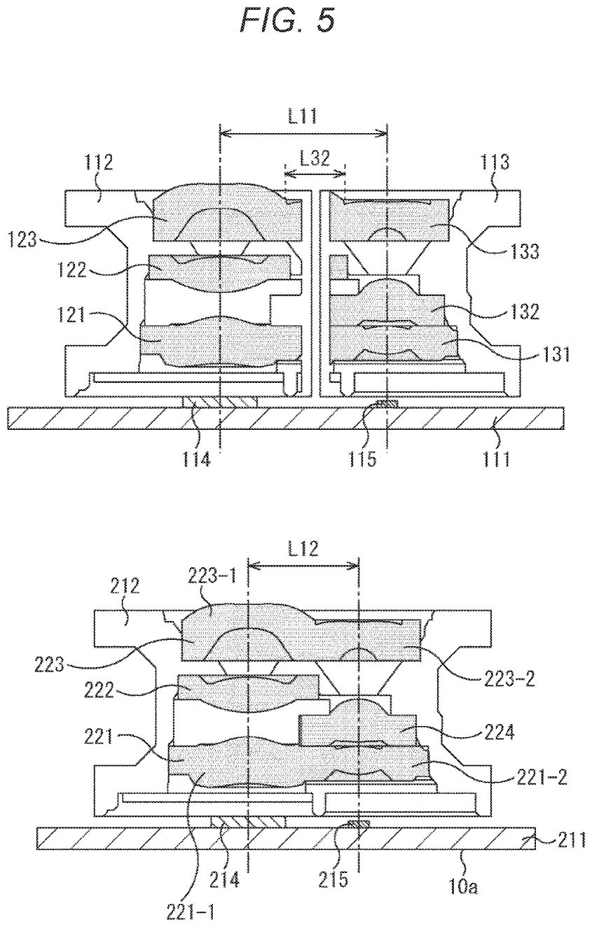

In the semiconductor device 10a depicted in FIG. 4, the lenses on the light receiving side and the lenses on the light emitting side are held by the single lens holder 212, which is different from the semiconductor device 100 depicted in FIG. 3. Thus, time required at the time of manufacturing can be shortened, and the semiconductor device 10a can be downsized. This will be described with reference to FIG. 5.

The upper diagram of FIG. 5 is the semiconductor device 100 depicted in FIG. 3, and the lower diagram of FIG. 5 is the semiconductor device 10a depicted in FIG. 4. As depicted in the upper diagram of FIG. 5, the baseline length of the semiconductor device 100 including the separate lens holders is the baseline length L11. As depicted in the lower diagram of FIG. 5, a baseline length of the semiconductor device 10a including the integrally formed lens is a baseline length L12. The baseline length L12 is shorter than the baseline length L11.

In the semiconductor device 100, the light-receiving-side lens holder 112 and the light-emitting-side lens holder 113 are separately provided and arranged with the predetermined interval. Therefore, the baseline length L11 includes a length of the predetermined interval and a thickness of a side surface of each of the light-receiving-side lens holder 112 and the light-emitting-side lens holder 113. On the other hand, the semiconductor device 10a does not have a length corresponding to the predetermined interval in the semiconductor device 100, and thus, the baseline length L12 is shorter than the baseline length L11 by at least this length.

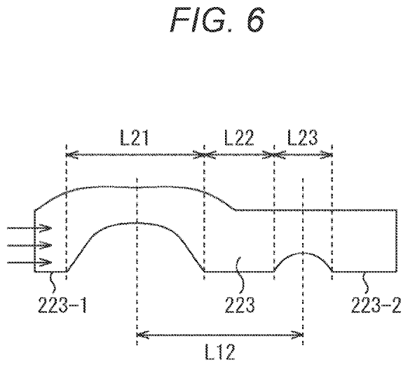

Since the semiconductor device 10a has a structure in which lengths corresponding to the thicknesses of the side surfaces of the light-receiving-side lens holder 112 and the light-emitting-side lens holder 113 can also be shortened, the baseline length L12 can be made even shorter than the baseline length L11. Such a configuration example will be described with reference to FIG. 6.

FIG. 6 is a diagram depicting the lens 223 held by the lens holder 212 of the semiconductor device 10a depicted in FIG. 4. The lens 223 has the configuration in which the lens 223-1 and the lens 223-2 are integrated. It is assumed that an effective diameter of the lens 223-1 is an effective diameter L21 and an effective diameter of the lens 223-2 is an effective diameter L23. The lens 223-1 and the lens 223-2 are connected at a portion outside the effective diameters. A region where the lens 223-1 and the lens 223-2 are connected is defined as a connection portion. The connection portion is located at a position sandwiched between the effective diameter L21 and the effective diameter L22, and a length thereof is a length L22.

The baseline length L12 can be expressed as L12=(L21/2)+L22+(L23/2). In a case where the baseline length L11 is similarly expressed and a length corresponding to the length L22 is expressed as a length L32, the baseline length L11 can be expressed as L11=(L21/2)+L32+(L23/2). A difference between the length of the baseline length L12 and the length of the baseline length L11 is caused by a difference in length between the length L12 and the length L32.

Referring to the upper diagram of FIG. 5, the length L32 is a length including the interval at which the light-receiving-side lens holder 112 and the light-emitting-side lens holder 113 are arranged, the thicknesses of the side surfaces of the respective light-receiving-side lens holder 112 and light-emitting-side lens holder 113, and a part of a portion outside the effective diameters of the held lenses (a flat portion provided to hold the lenses). This part of the portion outside the effective diameters of the lenses is a portion that can be used as a connection portion that connects the lenses, and a length thereof can be substantially the same as the length L22.

From such a fact, it is apparent that the length L32 is longer than the length L22. Since the length L22 is shorter than the length L32, it is apparent that the baseline length L12 including the length L22 is shorter than the baseline length L11 including the length L32. It is also apparent that further downsizing can be achieved by further shortening the length L22. Thus, the semiconductor device 10a can be downsized.

Referring again to FIG. 5, since the semiconductor device 100 includes the light-receiving-side lens holder 112 and the light-emitting-side lens holder 113, a process of storing the lens in the light-receiving-side lens holder 112 and a process of storing the lens in the light-emitting-side lens holder 113 are performed. In the semiconductor device 10a, the lens on the light receiving side and the lens on the light emitting side are integrated, and such an integrated lens is held by the lens holder 212, and thus, it is only necessary to store the lens in the lens holder 212. Thus, the time required at the time of manufacturing can be shortened according to the semiconductor device 10a to which the present technology is applied.

Although processes of separately attaching the light-receiving-side lens holder 112 and the light-emitting-side lens holder 113 to the substrate 111 are necessary in the semiconductor device 100, it is only necessary to perform a process of attaching the lens holder 212 to the substrate 211 in the semiconductor device 10a. Thus, in this respect as well, the time required at the time of manufacturing can be shortened according to the semiconductor device 10a.

In this manner, when the present technology is applied, the time required at the time of manufacturing can be shortened, and the semiconductor device 10a to be manufactured can be the downsized semiconductor device 10a.

FIG. 6 will be referred to again. The lens 223 can be formed using, for example, resin. At the time of forming the lens 223, for example, the lens 223 can be formed by pouring resin into a mold for forming the lens 223 from the left side as indicated by arrows in FIG. 6. In a case where the lens 223 is formed by pouring the resin, it is preferable that the connection portion connecting the lens 223-1 and the lens 223-2 have a shape maintaining a size in which the resin easily flows. For example, in a case where the connection portion is narrow, there is a possibility that the resin does not sufficiently flow to the lens 223-2 side, or a region that is not sufficiently filled with the resin is formed in the connection portion if the connection portion has a large step. In order to prevent such a situation, the connection portion is formed in a shape in which the resin sufficiently flows.

The lens 221 is also formed by pouring resin into a mold similarly to the lens 223 although not depicted. The lens 222 and the lens 224 that are not integrally formed can be similarly formed by pouring resin into a mold.

Note that the description will be continued here with resin, a lens formed using a material other than the resin can also be applied to the present technology. Although the description will be continued here assuming that the lenses 221 to 224 are resin lenses, all of the lenses 221 to 224 may be configured as resin lenses, or alternatively, one to three lenses among the lenses 221 to 224 may be configured as resin lenses, and the other lenses may be lenses formed using materials other than the resin.

As depicted in FIG. 6, the lens 223 has a configuration in which the lens 223-1 and the lens 223-2 having different optical characteristics are continuously and integrally formed. For example, the lens 223-1 is the lens on the light receiving side and has a function of collecting incident light, and the lens 223-2 is the lens on the light emitting side and has a function of diffusing light to be emitted.

The effective diameter L21 of the lens 223-1 and the effective diameter L23 of the lens 223-2 have different sizes. In this manner, the lens 223 is formed such that the lenses having different functions or different shapes as the optical characteristics can be treated as one integrated lens.

In other words, the lens 223 is a lens having different optical surfaces. The optical surface of the lens 223-1 and the optical surface of the lens 223-2 constituting the lens 223 are formed at different positions. The optical surface is an interface between the material of the lens 223 and air. In the optical surface, reflection, refraction, and transmission of light occur. Shapes of the optical surface include a flat surface, a spherical surface, and a free-form surface.

In the example depicted in FIG. 6, the optical surface of lens 223-1 is formed at a higher position than the optical surface of lens 223-2 in an optical axis direction. The lens 223 is a structure body in which a plurality of lenses having optical surfaces at different positions is continuous.

Note that the lens is described here as an example, but the present technology can also be applied to a structure body other than the optical structure body such as the lens. For example, the present technology can also be applied to an optical structure body such as a filter that transmits light having a predetermined wavelength. In this case, a structure body having a configuration in which a plurality of filters that transmit beams of light having different wavelengths is continuous is formed.

FIG. 4 will be referred to again. In the lens holder 212 depicted in FIG. 4, the lens 221-1, the lens 222, and the lens 223-1 arranged in an optical axis direction (vertical direction in the drawing) are held as the lenses on the light receiving side.

In the lens holder 212, the lens 221-2, the lens 224, and the lens 223-2 arranged in an optical axis direction are held as the lenses on the light emitting side.

In the following description, a lens formed as a structure body in which a plurality of lenses having different optical characteristics is continuous, such as the lens 223, is referred to as an integrally formed lens.

Here, the integrally formed lens will be continuously described by taking, as an example, a case where two lenses having different characteristics are integrated, but the present technology can also be applied to a case where two or more lenses are used to form the integrally formed lens.

Among the lenses held by the lens holder 212, the lens 221-1 and the lens 221-2 are formed as the integrally configured lens 221, and the lens 223-1 and the lens 223-2 are formed as the integrally configured lens 223.

In the semiconductor device 10a depicted in FIG. 4, an example in which three lenses are configured on the light receiving side and three lenses are configured on the light emitting side is depicted, and two of them are integrally formed lenses in the example. There may be one integrally formed lens.

In a case where one integrally formed lens is used, a lens attached to the uppermost side of the lens holder 212, in other words, the side farthest from a surface on which the imaging element 214 and the light emitting section 215 are provided can be configured as the integrally formed lens. When the lens mounted on the top of the lens holder 212 is the integrally formed lens, it is possible to prevent external dust and dirt from entering the inside of the lens holder 212.

When the lens on the uppermost side of the lens holder 212 is the integrally formed lens, vignetting can be suppressed. When the light-receiving-side lens holder 112 is present on the lateral side of the light-emitting-side lens holder 113 as in the semiconductor device 100 including the separate lens holders depicted in the upper diagram of FIG. 5, out of light emitted from the light-emitting-side lens holder 113. light having a large emission angle is likely to hit the side surface of the light-receiving-side lens holder 112.

However, when the lens 223 on the uppermost side of the lens holder 212 is used as the integrally formed lens as in the semiconductor device 10a including the integrally formed lens depicted on the lower side of FIG. 5, it is possible to prevent light having a large emission angle from hitting the lens holder as described above. Since such a situation can be prevented, the vignetting can be mitigated.

The lens on the uppermost side of the lens holder 212 generally tends to be large. When such a lens is configured as the integrally formed lens, downsizing can be achieved as compared with a case where an integrally formed lens is configured using another body. For example, when the lens 1123 and the lens 133 arranged at the top are configured as integrally formed lenses and provided on the two lens holders in the semiconductor device 100 depicted in FIG. 3, the semiconductor device 100 including the two lens holders can also be downsized.

In the semiconductor device 10a depicted in FIG. 4, all the lenses held by the lens holder 212 may be integrally formed lenses. The semiconductor device 10a depicted in FIG. 4 may be configured such that three integrally formed lenses are held by the lens holder 212. Any case where the number of integrally formed lenses held by the lens holder 212 is one or more corresponds to a range to which the present technology is applicable.

In the lens 221 included in the lens holder 212 of the semiconductor device 10a depicted in FIG. 4, a flat portion 221′ and a flat portion 221″ are formed at both ends. The flat portion 221′ and the flat portion 221″ are formed in regions outside the effective diameter of the lens. The flat portion 221′ and the flat portion 221″ are arranged to be in contact with holding sections 212-1′ and 212-1″ formed in the lens holder 212, respectively, whereby the lens 221 is held by the lens holder 212.

Similarly, a flat portion 223′ and a flat portion 223″ are formed at both ends of the lens 223. The flat portion 223′ and the flat portion 223″ are arranged to be in contact with holding sections 212-3′ and 212-3″ formed in the lens holder 212, respectively, whereby the lens 223 is held by the lens holder 212.

In this manner, the integrally formed lens 221 and the integrally formed lens 223 are held by the lens holder 212 at portions formed flat at both the ends of each of the lenses. It is also possible to adopt a configuration in which the connection portion of the lens 221 or the lens 223 where the lenses having different characteristics are connected to each other is not used to hold the lens. Even if a length of the length L2 corresponding to the length of the connection portion described with reference to FIG. 6 is shortened, a holding mechanism is not affected. Thus, it is also possible to adopt a configuration in which the length L2 is made shorter, and the semiconductor device 10a can be downsized.

The lens 222 and the lens 224 are not integrally formed lenses, but are lenses provided on the light receiving side and the light emitting side, respectively. How to hold such lenses by the lens holder 212 is appropriately set at the time of designing the lens holder 212. For example, in the semiconductor device 10a depicted in FIG. 4, the lens 224 has flat portions 224′ and 224″ at both ends, and the flat portions 224′ and 224″ are placed to be in contact with flat portions (one of the portions corresponds to the flat portion 221″ and the other portion corresponds to the connection portion) of the lens 221-2, thereby being held in the lens holder 212.

The lens 222 also has flat portions 222′ and 222″ at both ends, and is configured to be held by placing the flat portions 222′ and 222″ on a holding section 226 formed in the lens holder 212. The holding section 226 may be a spacing tube. One end of the holding section 226 is configured to be sandwiched between the flat portion 222″ of the lens 222 and the flat portion 222′ of the lens 224, and is configured such that the lens 222 and the lens 224 are not displaced from each other.

Shapes of the lenses 221 to 224 are configured to be suitable for collecting incident light on the light receiving side, and are configured to be suitable for diffusing light to be emitted on the light emitting side. The shapes of the lenses 221 to 224 depicted in FIG. 4 are given as examples, and are not described to be limited, and whether each of the lenses is formed as a concave lens or a convex lens, how to combine these lenses, a positional relationship among the respective lenses in the optical axis direction (vertical direction), and the like are appropriately set to be optimal.

<Configuration of Semiconductor Device According to Second Embodiment>

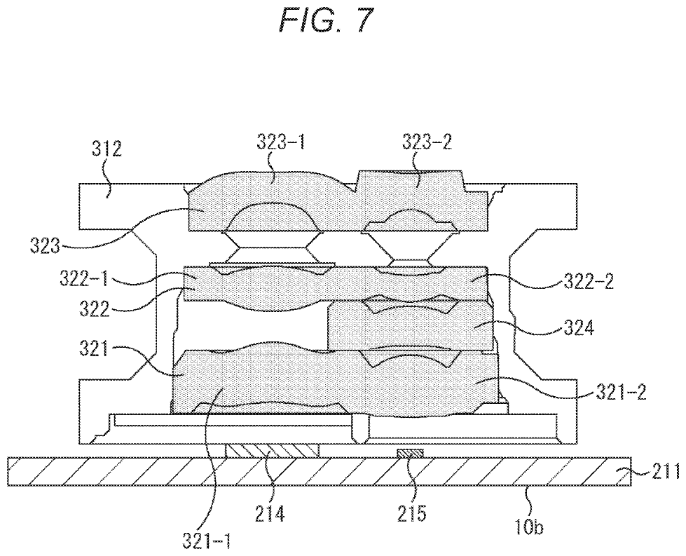

FIG. 7 is a diagram depicting a configuration example of a semiconductor device 10b according to a second embodiment. The technology applicable to the semiconductor device 10a in the first embodiment can also be applied to the following embodiments, and the description thereof will be appropriately omitted.

The semiconductor device 10a according to the first embodiment has been described with the example having the configuration in which three lenses are provided on the light receiving side and three lenses are provided on the light emitting side. The semiconductor device 10b according to the second embodiment is configured such that three lenses are provided on a light receiving side and four lenses are provided on a light emitting side.

A lens holder 312 of the semiconductor device 10b depicted in FIG. 7 holds an integrally formed lens 321, an integrally formed lens 322, and an integrally formed lens 323, and also holds a lens 324 as a lens on the light emitting side. The lens 321 is a lens having a shape in which a lens 321-1 on the light receiving side and a lens 321-2 on the light emitting side are continuous. The lens 322 is a lens having a shape in which a lens 322-1 on the light receiving side and a lens 322-2 on the light emitting side are continuous. The lens 323 is a lens having a shape in which a lens 323-1 on the light receiving side and a lens 323-2 on the light emitting side are continuous.

The semiconductor device 10b includes the lens 321-1, the lens 322-1, and the lens 323-1 in an optical axis direction as the lenses on the light receiving side (lenses collecting incident light). The semiconductor device 10b includes the lens 321-2, the lens 324, the lens 322-2, and the lens 323-2 in an optical axis direction as the lenses on the light emitting side (lenses diffusing light to be emitted).

The semiconductor device 10b depicted in FIG. 7 has a configuration in which the lens 321-1 which is the first on the light receiving side and the lens 321-2 which is the first on the light emitting side are connected, the lens 322-1 which is the second on the light receiving side and the lens 322-2 which is the third on the light emitting side are connected, and the lens 323-1 which is the third on the light receiving side and the lens 323-2 which is the fourth on the light emitting side are connected.

In this manner, it may be configured such that the number of the lenses on the light receiving side is different from the number of the lenses on the light emitting side and the integrally formed lens is formed by connecting lenses in different orders the light receiving side and the light emitting side to each other.

<Configuration of Semiconductor Device According to Third Embodiment>

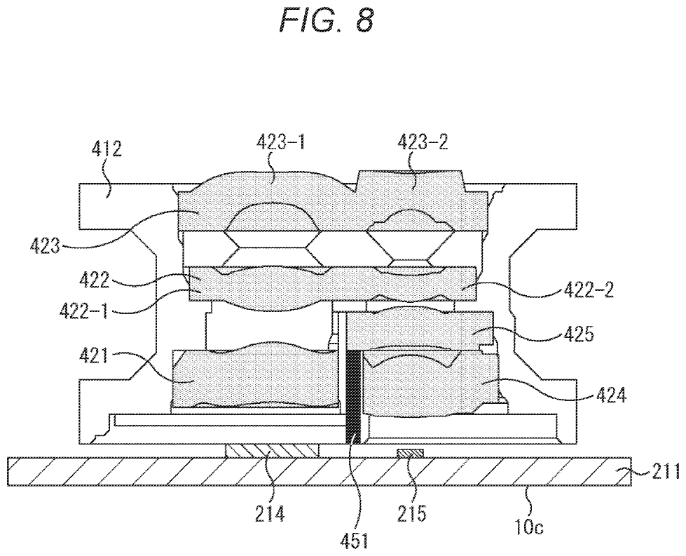

FIG. 8 is a diagram depicting a configuration example of a semiconductor device 10c according to a third embodiment to which the present technology is applied.

The semiconductor device 10c according to the third embodiment is similar to the semiconductor device 10b according to the second embodiment in that three lenses are provided on a light receiving side and four lenses are provided on a light emitting side, but has a difference that a light shielding wall 451 is formed.

A lens holder 412 of the semiconductor device 10c depicted in FIG. 8 holds an integrally formed lens 422 and an integrally formed lens 423. The lens holder 412 also holds a lens 421 as a lens on the light receiving side, and a lens 424 and a lens 425 as lenses on the light emitting side.

The lens 422 is a lens having a shape in which a lens 422-1 on the light receiving side and a lens 422-2 on the light emitting side are continuous. The lens 423 is a lens having a shape in which a lens 423-1 on the light receiving side and a lens 423-2 on the light emitting side are continuous.

The semiconductor device 10c includes the lens 421, the lens 422-1, and the lens 423-1 in an optical axis direction as the lenses on the light receiving side (lenses collecting incident light). The semiconductor device 10b includes the lens 424, the lens 425, the lens 422-2, and the lens 423-2 in an optical axis direction as the lenses on the light emitting side (lenses diffusing light to be emitted).

The semiconductor device 10c depicted in FIG. 8 has a configuration in which the lens 422-1 which is the second on the light receiving side and the lens 422-2 which is the third on the light emitting side are connected, and the lens 423-1 which is the third on the light receiving side and the lens 423-2 which is the fourth on the light emitting side are connected.

In this manner, it may be configured such that the number of the lenses on the light receiving side is different from the number of the lenses on the light emitting side and the integrally formed lens is formed by connecting lenses in different orders the light receiving side and the light emitting side to each other.

In the semiconductor device 10c depicted in FIG. 8, the light shielding wall 451 is provided between the lens 421 that is the first lens on the light receiving side and the lens 424 that is the first lens on the light emitting side. There is a possibility that a part of light emitted by the light emitting section 215 leaks to the light receiving side. For example, in a case where the lens 221 (321), arranged on a side close to the imaging element 214 as in the semiconductor device 10a (FIG. 4) and the semiconductor device 10b (FIG. 7), is an integrally formed lens, there is a possibility that the lens serves as a light guide path so that a part of the light emitted by the light emitting section 215 leaks to the light receiving side (the imaging element 214).

In order to prevent such leakage of light, in the semiconductor device 10c depicted in FIG. 8, a lens arranged on a side closest to the imaging element 214 is not an integrally formed lens, and the lens 421 and the lens 424 are provided on the light receiving side and the light emitting side, respectively. Since the lens 421 and the lens 424 are separate bodies, it is possible to reduce the possibility of serving as the light guide path. Moreover, light that leaks can be reduced by providing the light shielding wall 451.

The light shielding wall 451 includes a material capable of shielding light. In the configuration depicted in FIG. 8, the light shielding wall 451 is also used as a member that supports the lens 425. Flat portions are formed in regions outside an effective diameter at both ends of the lens 425, and one end of the flat portions is in contact with one end of the light shielding wall 451. The lens 425 is configured to be held by the light shielding wall 451 and a holding section formed in the lens holder 412.

A spacing tube may be used as a member that supports the lens 425. The spacing tube is used as a member for maintaining an interval between a lens and a lens constant. The spacing tube may be used as the light shielding wall 451. For example, the spacing tube may be formed using a material having a high light shielding property, and may be configured to have a function of holding the lens and a function as the light shielding wall 451.

When the light shielding wall 451 is provided in this manner, the leakage of light can be prevented, and the leaking light can be prevented from being incident to the imaging element 214.

<Configuration of Semiconductor Device According to Fourth Embodiment>

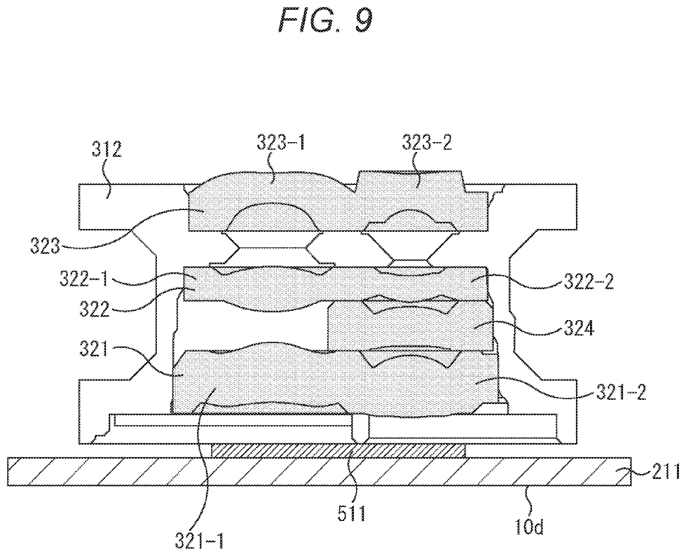

FIG. 9 is a diagram depicting a configuration example of a semiconductor device 10d according to a fourth embodiment to which the present technology is applied.

The semiconductor device 100 described with reference to FIG. 3 and the semiconductor devices 10a to 10c in the first to third embodiments have been described by exemplifying the case where the present technology is applied to the device that performs distance measurement. The present technology can also be applied to, for example, a device that images a subject and acquires a color image, an image of infrared light, and the like. As the fourth embodiment and a fifth embodiment, a case where the present technology is applied to the semiconductor device 10 that acquires a color image and the like will be described.

FIG. 9 is the diagram depicting the configuration example of the semiconductor device 10d according to the fourth embodiment. The semiconductor device 10d is different from the semiconductor device 10b according to the second embodiment depicted in FIG. 7 in that an imaging element 511 is arranged instead of the light emitting section 215, and the other points are similar, and thus, will be denoted by the same reference signs, and the description thereof will be omitted.

In the semiconductor device 10d, the imaging element 511 is arranged between the lens holder 312 and the substrate 211. The imaging element 511 is arranged not only on a side referred to as the light receiving side in the first to third embodiments but also on the side referred to as the light emitting side. Furthermore, a plurality of light receiving elements (the imaging elements 511) may be provided, or one light receiving element may be provided.

It is assumed that the left side and the right side in the drawing are a light receiving side A and a light receiving side B, respectively. Regarding the imaging element 511, the single imaging element 511 is arranged on the light receiving side A and the light receiving side B in FIG. 9, but imaging elements may be arranged respectively on the light receiving side A and the light receiving side B. In a case where the single imaging element 511 is provided as depicted in FIG. 9, the pixel 50 (FIG. 2) is not necessarily provided between the light receiving side A and the light receiving side B (in a region outside an effective diameter).

The light receiving side A and the light receiving side B can be configured to have mutually different optical characteristics. For example, the semiconductor device 10d can be configured such that the light receiving side A functions as an imaging section that images a still image and the light receiving side B functions as an image capturing section that captures a moving image. In this case, a lens and the imaging element 511 on the light receiving side A are configured to be suitable for the imaging of a still image, and a lens and the imaging element 511 on the light receiving side B are configured to be suitable for the capturing of a moving image.

For example, the semiconductor device 10d may be configured to perform imaging with different resolutions and different exposure time periods between the light receiving side A and the light receiving side B. In such a case, for example, the light receiving side A of the semiconductor device 10d can be configured as an imaging section that performs imaging with long-time exposure, the light receiving side B can be configured as an imaging section that performs imaging with short-time exposure, and the semiconductor device 10d can be configured to generate an image with an expanded dynamic range by combining images obtained by the two imaging sections.

For example, the light receiving side A of the semiconductor device 10d can also be configured as an imaging section that images an image with visible light, and the light receiving side B can also be configured as an imaging section that images an image with infrared light. In this case, a lens and the imaging element 511 on the light receiving side A are configured to be suitable for the imaging of visible light, and a lens and the imaging element 511 on the light receiving side B are configured to be suitable for capturing of infrared light. In this case, for example, the lens 423 may be configured as a filter such that a filter corresponding to the lens 423-1 is a filter that transmits visible light, and a filter corresponding to the lens 423-2 is a filter that transmits infrared light.

In this manner, the light receiving side A and the light receiving side B can be configured to have mutually different functions, and lenses suitable for the functions can be held by the lens holder 412. A predetermined number of lenses among a plurality of lenses held by the lens holder 412 can be configured as integrally formed lenses. The integrally formed lens can be configured as a lens to which lenses having different optical characteristics suitable for different functions are connected.

<Configuration of Semiconductor Device According to Fifth Embodiment>

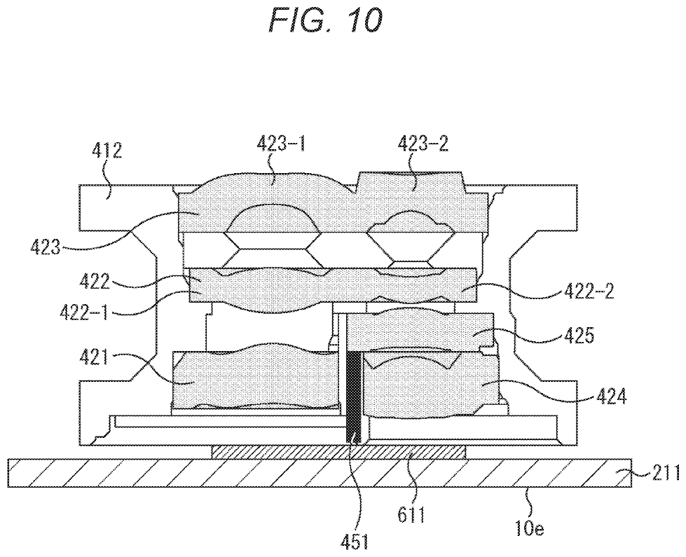

FIG. 10 is a diagram depicting a configuration example of a semiconductor device 10e according to the fifth embodiment to which the present technology is applied.

The semiconductor device 10e according to the fifth embodiment depicted in FIG. 10 has a configuration in which the semiconductor device 10c (FIG. 8) according to the third embodiment and the semiconductor device 10d (FIG. 9) according to the fourth embodiment are combined. The same sites as those of the semiconductor device 10c according to the third embodiment will be denoted by the same reference signs, and the description thereof will be omitted.

The semiconductor device 10e according to the fifth embodiment includes the light shielding wall 451 similarly to the semiconductor device 10c according to the third embodiment, and includes an imaging element 611 instead of the light emitting section 215 similarly to the semiconductor device 10d according to the fourth embodiment. The imaging element 611 corresponds to the imaging element 511 of the semiconductor device 10d depicted in FIG. 9.

As depicted in FIG. 10, it is also possible to adopt a configuration in which the light shielding wall 451 is provided in the lens holder 412 to suppress leakage of light.

According to the present technology, the semiconductor device 10 can be downsized. The semiconductor device 10 to which the present technology is applied can shorten the time required at the time of manufacturing and can reduce the number of processes.

<Application Example to Mobile Body>

The technology according to the present disclosure (present technology) can be applied to various products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a ship, and a robot.

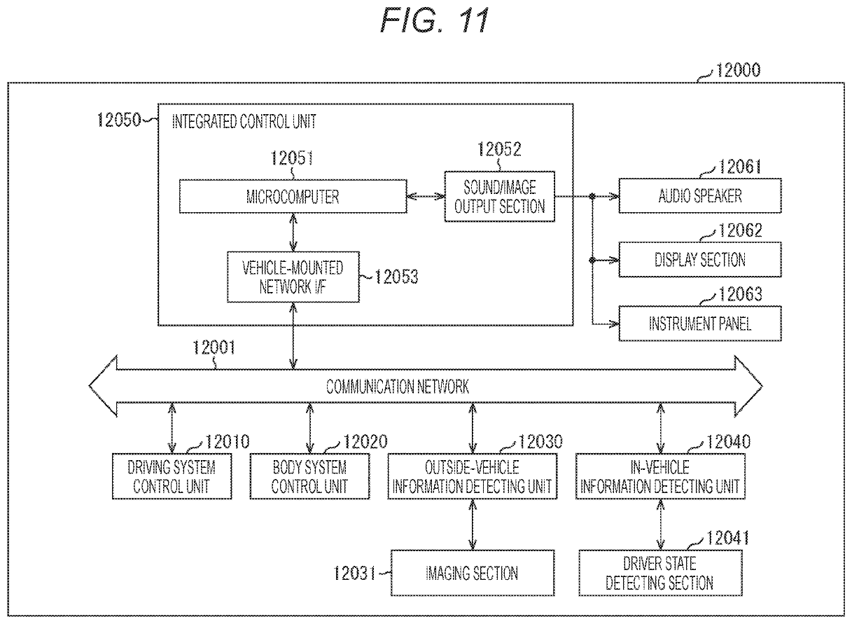

FIG. 11 is a block diagram depicting an example of a schematic configuration of a vehicle control system as an example of a mobile body control system to which the technology according to the present disclosure can be applied.

A vehicle control system 12000 includes a plurality of electronic control units connected to each other via a communication network 12001. In the example depicted in FIG. 11, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are depicted as functional configurations of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. Furthermore, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

Furthermore, the microcomputer 12051 can perform cooperative control intended for automated driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 11, an audio speaker 12061, a display section 12062, and an instrument panel 12063 are illustrated as the output device. The display section 12062 may, for example, include at least one of an on-board display and a head-up display.

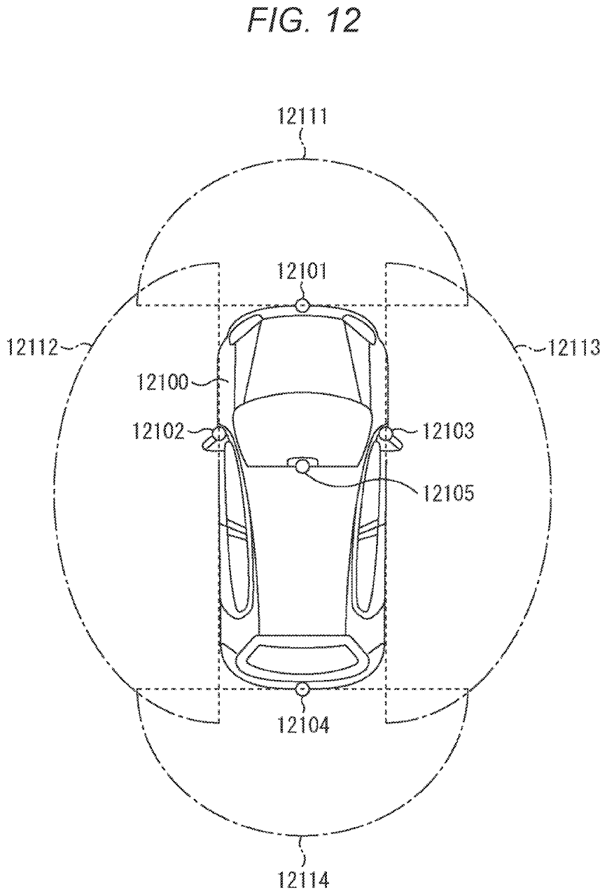

FIG. 12 is a diagram depicting an example of the installation position of the imaging section 12031.

In FIG. 12, the imaging section 12031 includes imaging sections 12101, 12102, 12103, 12104, and 12105.

The imaging sections 12101, 12102, 12103, 12104, and 12105 are, for example, arranged at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 12 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. For example, a bird's-eye image of the vehicle 12100 as viewed from above is obtained by superimposing image data imaged by the imaging sections 12101 to 12104.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Moreover, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. Furthermore, the sound/image output section 12052 may also control the display section 12062 so that an icon or the like representing the pedestrian is displayed at a desired position.

In the present specification, the system represents the entire apparatus including a plurality of devices.

The effects described in the present specification are merely examples and are not limited, and other effects may be present.

Embodiments of the present technology are not limited to the above-described embodiments, and various modifications can be made within a scope not departing from a gist of the present technology.

The present technology can also have the following configurations.

(1)

A semiconductor device including:
a plurality of first optical structure bodies arranged in a first optical axis direction; and
a plurality of second optical structure bodies arranged in a second optical axis direction, in which
at least one of the plurality of first optical structure bodies and at least one of the plurality of second optical structure bodies arranged in a direction perpendicular to the optical axis directions are optical structure bodies having a structure in which the first optical structure body and the second optical structure body are continuous.

(2)

The semiconductor device according to (1), in which
the first optical structure body and the second optical structure body have different optical characteristics.

(3)

The semiconductor device according to (1) or (2), in which
the first optical structure body and the second optical structure body are lenses.

(4)

The semiconductor device according to any one of (1) to (3), in which
in the optical structure bodies having the continuous structure, positions of an optical surface of the first optical structure body and an optical surface of the second optical structure body are different.

(5)

The semiconductor device according to any one of (1) to (4), in which
the first optical structure body is arranged on a light receiving element, and
the second optical structure body is arranged on a light emitting element.

(6)

The semiconductor device according to any one of (1) to (4), in which
the first optical structure body and the second optical structure body are arranged on a light receiving element.

(7)

The semiconductor device according to (5) or (6), in which
the optical structure bodies having the continuous structure are arranged on a side different from a side on which the light receiving element is arranged.

(8)

The semiconductor device according to any one of (1) to (7), further including
a light shielding wall provided between the first optical structure body and the second optical structure body.

(9)

The semiconductor device according to any one of (1) to (8), in which
the first optical structure bodies and the second optical structure bodies are provided in different numbers.

(10)

An optical structure body
having a structure in which a first optical structure body and a second optical structure body respectively having optical surfaces at different positions in an optical axis direction are continuous.

(11)

The optical structure body according to (10), in which
the first optical structure body and the second optical structure body have different optical characteristics.

(12)

The optical structure body according to (10) or (11), in which
the first optical structure body and the second optical structure body are lenses.

### REFERENCE SIGNS LIST

10 Semiconductor device
11 Lens
12 Light receiving section
13 Signal processing section
14 Light emitting section
15 Light emission control section
21 Pattern switching section
22 Distance image generating section
41 Pixel array section
42 Vertical drive section
43 Column processing section
44 Horizontal drive section
45 System control section
46 Pixel drive line
47 Vertical signal line
48 Signal processing section
50 Pixel
211 Substrate
212 Lens holder
214 Imaging element
215 Light emitting section
221, 222, 223, 224 Lens
226 Holding section
312 Lens holder
321, 322, 323, 324 Lens
412 Lens holder
421, 422, 423, 424, 425 Lens
451 Light shielding wall
511, 611 Imaging element

What is claimed is:

1. A semiconductor device, comprising:
a plurality of first optical structure bodies arranged in a first optical axis direction; and
a plurality of second optical structure bodies arranged in a second optical axis direction, wherein
at least one of the plurality of first optical structure bodies and at least one of the plurality of second optical structure bodies arranged in a direction perpendicular to the optical axis directions are optical structure bodies having a structure in which the first optical structure body and the second optical structure body are continuous.

2. The semiconductor device according to claim 1, wherein
the first optical structure body and the second optical structure body have different optical characteristics.

3. The semiconductor device according to claim 1, wherein
the first optical structure body and the second optical structure body are lenses.

4. The semiconductor device according to claim 1, wherein
in the optical structure bodies having the continuous structure, positions of an optical surface of the first optical structure body and an optical surface of the second optical structure body are different.

5. The semiconductor device according to claim 1, wherein
the first optical structure body is arranged on a light receiving element, and
the second optical structure body is arranged on a light emitting element.

6. The semiconductor device according to claim 1, wherein
the first optical structure body and the second optical structure body are arranged on a light receiving element.

7. The semiconductor device according to claim 5, wherein
the optical structure bodies having the continuous structure are arranged on a side different from a side on which the light receiving element is arranged.

8. The semiconductor device according to claim 1, further comprising
a light shielding wall provided between the first optical structure body and the second optical structure body.

9. The semiconductor device according to claim 1, wherein
the first optical structure bodies and the second optical structure bodies are provided in different numbers.

10. An optical structure body,
comprising a structure in which a first optical structure body and a second optical structure body respectively having optical surfaces at different positions in an optical axis direction are continuous.

11. The optical structure body according to claim 10, wherein
the first optical structure body and the second optical structure body have different optical characteristics.

12. The optical structure body according to claim 10, wherein
the first optical structure body and the second optical structure body are lenses.
